(19) United States
(12) Patent Application Publication
(10) Pub. No.: US 2025/0327879 A1
(43) Pub. Date: Oct. 23, 2025

(54) MONITORING HEALTH OF CAPACITOR OF POWER CONVERTER

(71) Applicant: Rolls-Royce Deutschland Ltd & Co KG, Blankenfelde-Mahlow (DE)

(72) Inventors: Sivakumar NADARAJAN, Singapore (SG); Viswanathan VAIYAPURI, Singapore (SG); Mohamed Sathik MOHAMED HALICK, Singapore (SG)

(21) Appl. No.: 19/084,474

(22) Filed: Mar. 19, 2025

(30) Foreign Application Priority Data
Apr. 19, 2024 (GB) 2405505.5

(51) Int. Cl. G01R 31/64; H02H 7/122

(52) U.S. Cl. CPC G01R 31/64; H02H 7/1225

(57) ABSTRACT

A method for monitoring a health of a capacitor of a power converter includes acquiring a direct current (DC) link capacitor voltage, an input current, phase currents, and switching pulses of the power converter. The method further includes calculating a DC link current based on the switching pulses and the phase currents, calculating a capacitor current based on the DC link current and the input current; applying a Goertzel algorithm to determine a first z-domain equation of the capacitor current and a second z-domain equation of the DC link capacitor voltage, determining an equivalent series resistance (ESR) and an estimated capacitance of the capacitor based on the first z-domain equation and the second z-domain equation, and comparing the estimated ESR with an initial ESR and/or the estimated capacitance with an initial capacitance.

The present patent document claims the benefit of United Kingdom Patent Application No. GB 2405505.5, filed Apr. 19, 2024, which is hereby incorporated by reference in its entirety.

### TECHNICAL FIELD

The present disclosure relates to a method for monitoring a health of a capacitor of a power converter.

### BACKGROUND

Electrical devices, such as power converters, are used in a multitude of applications where an efficient management and transformation of electrical energy is required. The power converters may be employed where an alternating current is the primary mode of power delivery, such as in renewable energy integration, vehicular propulsion, and various industrial processes. Despite their role, the power converters may also be susceptible to operational disruptions due to component degradation, which may lead to significant downtime and maintenance costs. The component degradation may stem from thermal and electrical stress.

One of the weakest components in a power converter system may be capacitors. Failures of the capacitors may be prevented by employing a suitable capacitor condition monitoring system to identify and predict capacitor degradation to estimate a remaining useful life of the capacitors.

Efforts to enhance reliability in the power converters have led to development of diagnostic tools aimed at assessing the health of the capacitors. However, current methods require additional hardware or modification in the existing hardware. Therefore, the current methods may not be suitable for commercial off-the-shelf power converters and may limit adaptability across different technologies prevalent in the field.

A method capable of estimating a condition of the capacitors without any additional hardware or modifications to existing hardware may offer substantial advantages in applications where safety and reliability are of high importance.

For capacitors, equivalent series resistance (ESR) and capacitance are widely used degradation indicators, wherein ESR is most commonly used for aluminum electrolytic, and capacitance is used for aluminum electrolytic, film, and ceramic types. Most of the existing methods focuses on only one of these two parameters.

Therefore, the industry recognizes the importance of a versatile and integrated approach to health monitoring of the capacitors of the power converters that may operate with existing system configurations and provide comprehensive diagnostics.

There is a need to provide a method for monitoring a health of a capacitor of a power converter that addresses the aforementioned shortcomings or at least provides a useful alternative to such methods.

### SUMMARY

In accordance with a first aspect of the present disclosure, a method for monitoring a health of a capacitor of a power converter is disclosed. The method includes acquiring a DC link capacitor voltage Vac, an input current Iᵢₙ, phase currents Iₐ, I_{b}, I_{c}, and switching pulses SP1, SP2, SP3 of the power converter. The method further includes calculating a DC link current I_{dc} based on the switching pulses SP1, SP2, SP3 and the phase currents Iₐ, I_{b}, I_{c}. The method further includes calculating a capacitor current I_{cap} based on the DC link current I_{dc} and the input current Iᵢₙ. The method further includes applying Goertzel algorithm to determine a first z-domain equation H(z)I_{cap} of the capacitor current I_{cap} and a second z-domain equation H(z)V_{dc} of the DC link capacitor voltage V_{dc}. The method further includes determining an estimated equivalent series resistance (ESR) and an estimated capacitance of the capacitor based on the first z-domain equation H(z)I_{cap} of the capacitor current I_{cap} and the second z-domain equation H(z)V_{dc} of the DC link capacitor voltage V_{dc}. The method further includes retrieving an initial ESR and an initial capacitance of the capacitor. The method further includes comparing the estimated ESR with the initial ESR and/or the estimated capacitance with the initial capacitance to determine when the capacitor is degraded, short-circuited, or open-circuited.

The method according to the present disclosure may enable equipment health monitoring (EHM) and remaining useful life estimation of the capacitor in the power converter. The method may be applied to existing power converters by accessing terminals that may be available for a user by acquiring the DC link capacitor voltage V_{dc}, the input current Iᵢₙ, the phase currents Iₐ, I_{b}, I_{c}, and the switching pulses SP1, SP2, SP3 of the power converter. These parameters may be easy to obtain using available data and using inexpensive sensors and may not require any customized circuits to extract any signature. Therefore, the method may be applied to any commercial off-the-shelf as well as in-house power converter systems. The method may further provide an early detection of degradation, short-circuits, or open-circuits, which further may enable to prevent the power converter failures. The method may therefore reduce maintenance costs. Further, the method uses the estimated capacitance and the estimated ESR, and therefore may be applied to dominant capacitor technologies.

In a further development, the method includes pausing an operation of the power converter upon determining that the capacitor is degraded, short-circuited, or open-circuited.

Pausing the operation of the power converter upon determining that the capacitor is degraded, short-circuited, or open-circuited may prevent any occurrence of damage to the power converter and/or a load electrically connected to the power converter.

In a further development, the DC link capacitor voltage is acquired from a voltage sensor. The voltage sensor used to acquire the DC link capacitor voltage may be an inexpensive voltage sensor.

In a further development, the input current is acquired from an input current sensor. The input current sensor used to acquire the input current may be an inexpensive current sensor.

In a further development, the phase currents are acquired from corresponding phase current sensors. The phase current sensors used to acquire the phase currents may be inexpensive current sensors.

In a further development, the switching pulses are acquired from a controller of the power converter. The switching pulses may be readily and easily acquired from the controller of the power converter.

In a further development, the DC link current is calculated from the equation:

$${I}_{d c} = SP 1 * {I}_{a} + S P 2 * {I}_{b} + SP 3 * {I}_{c} .$$

Therefore, the DC link current may be simply calculated using the switching pulses and the phase currents, which may be acquired using inexpensive current sensors.

In a further development, the capacitor current is calculated by subtracting the DC link current from the input current.

Therefore, the capacitor current may be easily determined in a simplified manner without any additional components or modifications by employing inexpensive current and voltage sensors.

In a further development, the first z-domain equation of the capacitor current is:

$$H ( z ) Icap = \frac{1 - {w}^{k x} {NxZ}^{- 1}}{1 - 2 cos ( \frac{2 π kx}{N x} ) {Z}^{- 1} + {Z}^{- 2}} * Icap$$

wherein Nx is a number of samples and Kx is:

$$K x = \frac{N x}{1 / Nx * Ts}$$

wherein Ts is a sampling time.

The first z-domain equation may provide efficient evaluation of the capacitor current.

In a further development, the second z-domain equation of the DC link capacitor voltage is:

$$H ( z ) Vdc = \frac{1 - {w}^{k x} {NxZ}^{- 1}}{1 - 2 c os ( \frac{2 π kx}{N x} ) {Z}^{- 1} + {Z}^{- 2}} * Vdc$$

wherein Nx is the number of samples and kx is:

$$K x = \frac{N x}{1 / Nx * Ts}$$

wherein Ts is the sampling time.

The second z-domain equation may provide efficient evaluation of the capacitor voltage.

In a further development, the estimated ESR of the capacitor is estimated from the equation:

$$estimated ESR = Real ( \frac{H ( z ) V d c}{H ( z ) I c a p} )$$

The estimated ESR may be simply and accurately estimated using the first and second z-domain equations from the above equation.

In a further development, the method includes identifying a dominant frequency component based on the DC link capacitor voltage.

The dominant frequency component may be used to estimate the estimated capacitance of the capacitor.

In a further development, the estimated capacitance of the capacitor is estimated from the equation:

$$estimated capacitance = Imag ( \frac{H ( z ) Vdc}{H ( z ) Icap} ) * abs ( 1 / ( 2 * pi * fd ) )$$

The estimated capacitance may be simply and accurately estimated using the first and second z-domain equations from the above equation.

In a further development, the method includes indicating that the capacitor is degraded when the estimated ESR is greater than the initial ESR by at least 10% of the initial ESR.

Upon receiving an indication that the capacitor is degraded, a user or a controller may decide the subsequent acts (e.g., to pause or stop an operation of the power converter) accordingly.

In a further development, the method includes indicating that the capacitor is short-circuited when the estimated ESR is less than the initial ESR by at least 100% of the initial ESR.

Upon receiving an indication that the capacitor is short-circuited, the user or the controller may decide the subsequent acts (e.g., to pause or stop the operation of the power converter) accordingly.

In a further development, the method includes indicating that the capacitor is degraded when the estimated capacitance is less than the initial capacitance by at least 5% of the initial capacitance and at most 50% of the initial capacitance.

Upon receiving an indication that the capacitor is degraded, the user or the controller may decide the subsequent acts (e.g., to pause or stop the operation of the power converter) accordingly.

In a further development, the method includes indicating that the capacitor is open-circuited when the estimated capacitance is less than the initial capacitance by at least 50% of the initial capacitance.

Upon receiving an indication that the capacitor is open-circuited, the user or the controller may decide the subsequent acts (e.g., to pause or stop the operation of the power converter) accordingly.

According to a second aspect, a system is disclosed. The system includes a processor and a memory having stored therein a plurality of instructions that when executed by the processor causes the system to perform the method of the first aspect.

The method for monitoring the health of the capacitor of the power converter according to the first aspect of the disclosure and the system according to the second aspect of the disclosure may include identical or similar developments, as described herein. Therefore, a development of one aspect of the disclosure is also applicable to another aspect of the disclosure.

These and other aspects of the method of the present disclosure will be apparent from and elucidated with reference to the embodiments described hereinafter. The embodiments of the method are described in the following based on the drawings. The latter is not necessarily intended to represent the embodiments to scale. Drawings are, where useful for explanation, shown in schematized and/or slightly distorted form. With regard to additions to the teachings immediately recognizable from the drawings, reference is made to the relevant state-of-the-art. Furthermore, modifications and changes may be made to the form and detail of an embodiment without deviating from the general idea of the disclosure. The features of the method of the present disclosure in the description, in the drawings, and in the claims may be essential for a further development of the method either individually or in any combination.

In addition, all combinations of at least two of the features disclosed in the description, drawings, and/or claims fall within the scope of the disclosure. The general idea of the disclosure is not limited to the exact form or detail of the embodiments shown and described below, or to an object which would be limited in comparison to the object claimed in the claims. For specified design ranges, values within the specified limits are also disclosed as limit values and thus arbitrarily applicable and claimable.

### BRIEF DESCRIPTION OF THE DRAWINGS

Further advantages, features, and details of the present disclosure result from the following description of the embodiments as well as from the drawings.

FIG. 1 depicts a schematic circuit diagram of a power converter, according to an embodiment of the present disclosure.

FIG. 2 depicts a schematic block diagram of a system, according to an embodiment of the present disclosure.

FIG. 3 depicts a flow chart for a method for monitoring a health of a capacitor of the power converter, according to an embodiment of the present disclosure.

FIG. 4 depicts an exemplary graphical representation of current phases.

FIG. 5 depicts an exemplary graphical representation of an input current, a DC link current and a DC link current.

FIG. 6 depicts an exemplary graph depicting an amplitude versus a frequency of a DC link capacitor voltage.

FIG. 7 depicts a flow chart of a method for determining an estimated equivalent series resistance (ESR) of the capacitor, according to an embodiment of the present disclosure.

FIG. 8 depicts a flow chart of a method for determining an estimated capacitance of the capacitor, according to an embodiment of the present disclosure.

### DETAILED DESCRIPTION

Aspects and embodiments of the present disclosure are now discussed with reference to the accompanying figures. Further aspects and embodiments will be apparent to those skilled in the art.

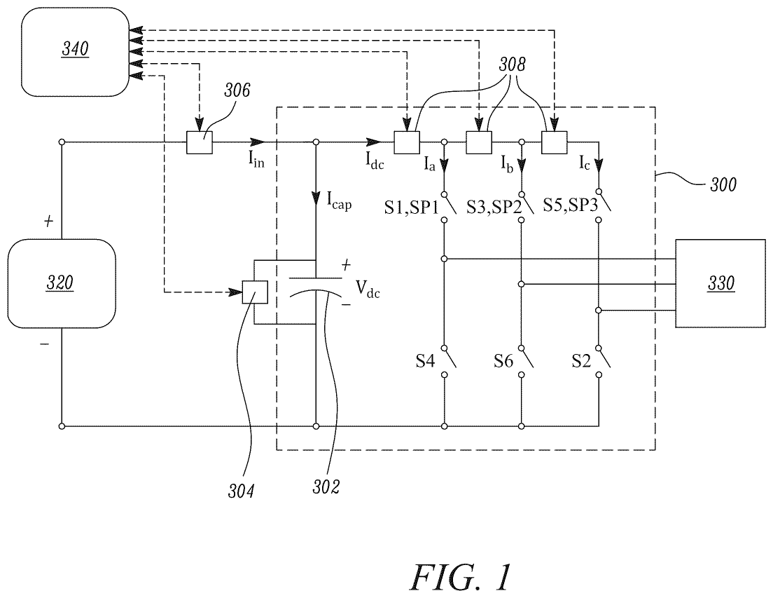

FIG. 1 shows a schematic circuit diagram of a power converter 300, according to an embodiment of the present disclosure. In the illustrated embodiment of FIG. 1, the power converter 300 is a three-phase inverter. Further, the power converter 300 may be a commercial off-the-shelf power converter.

The power converter 300 includes a plurality of switches S1, S2, S3, S4, S5, S6. In the illustrated example of FIG. 1, the power converter 300 includes six switches. However, in some other embodiments, the power converter 300 may include any number of switches based on desired application attributes. The power converter 300 further includes a capacitor 302 electrically connected in parallel with the plurality of switches S1, S2, S3, S4, S5, S6. In some embodiments, the capacitor 302 is a DC link capacitor. In some embodiments, the capacitor 302 may provide energy for one switching cycle of the power converter 300.

In the illustrated example of FIG. 1, the power converter 300 is electrically connected to a DC source 320. The DC source 320 is configured to provide a DC power to the power converter 300. In some embodiments, the DC source 320 may be a rectifier. In some embodiments, the DC source 320 may be a battery. Further, the power converter 300 is electrically connected to a load 330. In some embodiments, the load 330 may be a three-phase motor.

In some cases, the DC source 320 may introduce parasitic inductance in the power converter 300. When the DC source 320 is the rectifier, the DC source 320 may introduce its own harmonics into the power converter 300. In such cases, the capacitor 302 may be used to eliminate the harmonics and provide a fundamental component to the power converter 300. Hence, the capacitor 302 may play an important role in the operation of the power converter 300.

As shown in FIG. 1, the DC source 320 provides an input current Iᵢₙ to the power converter 300. Further, an electrical voltage across the capacitor 302 is a DC link capacitor voltage V_{dc}. Furthermore, each phase of the power converter 300 receives a corresponding phase current Iₐ, I_{b}, I_{c}. Specifically, the phase of the power converter 300 including the switches S1, S4 receives the phase current Iₐ, the phase of the power converter 300 including the switches S3, S6 receives the phase current I_{b}, and the phase of the power converter 300 including the switches S5, S2 receives the phase current I_{c}. Furthermore, each phase of the power converter 300 receives a corresponding switching pulse SP1, SP2, SP3. Specifically, the phase of the power converter 300 including the switches S1, S4 receives the switching pulse SP1, the phase of the power converter 300 including the switches S3, S6 receives the switching pulse SP2, and the phase of the power converter 300 including the switches S5, S2 receives the switching pulse SP3. In some embodiments, the switching pulses SP1, SP2, SP3 may be provided by a controller 340. In some embodiments, the controller 340 may be a component of the power converter 300. In some embodiments, the power converter 300 may operate using a typical pulse width modulation (PWM) technique. Switching of the power converter 300 may produce a current which has a fundamental component and many harmonics. Both the fundamental and harmonic currents are drawn from the capacitor 302.

In some embodiments, the DC link capacitor voltage V_{dc} is acquired from a voltage sensor 304. Further, in some embodiments, the input current Iᵢₙ is acquired from an input current sensor 306. In some embodiments, the phase currents Iₐ, I_{b}, I_{c} are acquired from corresponding phase current sensors 308. In some embodiments, the switching pulses SP1, SP2, SP3 are acquired from the controller 340 of the power converter 300.

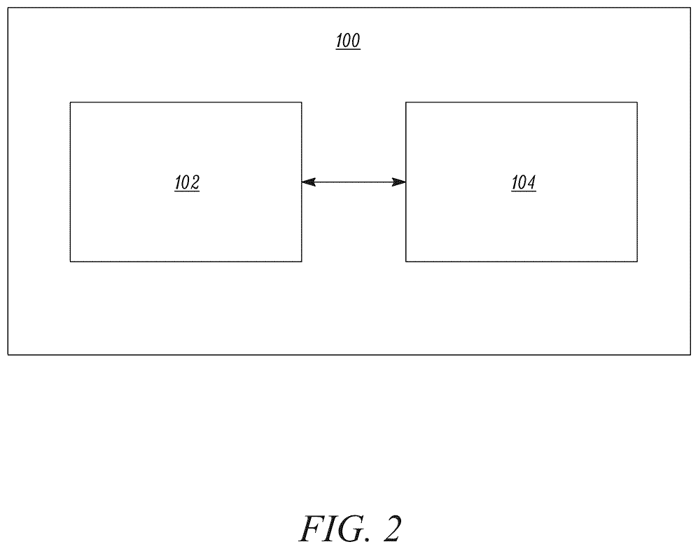

FIG. 2 shows a schematic block diagram of a system 100, according to an embodiment of the present disclosure. The system 100 includes a processor 102 and a memory 104 having stored therein a plurality of instructions that when executed by the processor 102 causes the system 100 to perform operations described herein.

Referring to FIGS. 1 and 2, in some embodiments, the processor 102 is communicably connected to the input current sensor 306, the voltage sensor 304, and the phase current sensors 308. The processor 102 may monitor the health of the capacitor 302 of the power converter 300 by performing the operations described herein.

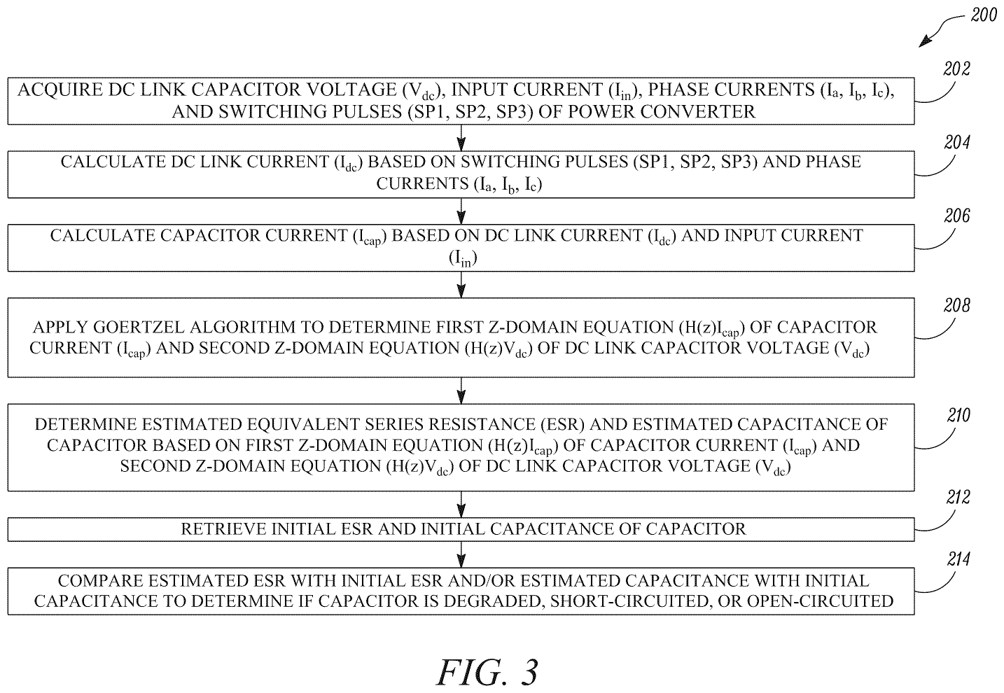

FIG. 3 shows a flow chart for a method 200 for monitoring the health of the capacitor 302 of the power converter 300 shown in FIG. 1, according to an embodiment of the present disclosure. The method 200 is described with further reference to FIGS. 1 and 2. In some embodiments, the processor 102 causes the system 100 to perform the method 200.

At act 202, the method 200 includes acquiring the DC link capacitor voltage Vac, the input current Iᵢₙ, the phase currents Iₐ, I_{b}, I_{c}, and the switching pulses SP1, SP2, SP3 of the power converter 300.

As discussed above, in some embodiments, the DC link capacitor voltage V_{dc} is acquired from the voltage sensor 304, the input current Iᵢₙ is acquired from the input current sensor 306, the phase currents Iₐ, I_{b}, I_{c} are acquired from the corresponding phase current sensors 308, and the switching pulses SP1, SP2, SP3 are acquired from the controller 340 of the power converter 300.

At act 204, the method 200 includes calculating a DC link current I_{dc} based on the switching pulses SP1, SP2, SP3 and the phase currents Iₐ, I_{b}, I_{c}. In some embodiments, the DC link current I_{dc} is calculated from the equation:

$${I}_{d c} = S P 1 * {I}_{a} + S P 2 * {I}_{b} + S P 3 * {I}_{c} .$$

At act 206, the method 200 includes calculating a capacitor current I_{cap} based on the DC link current I_{dc} and the input current Iᵢₙ. In some embodiments, the capacitor current I_{cap} is calculated by subtracting the DC link current I_{dc} from the input current Iᵢₙ, i.e., I_{cap}=Iᵢₙ−I_{dc}. The capacitor current I_{cap} may produce a variation in the DC link voltage V_{dc}.

Therefore, the capacitor current I_{cap} may be easily determined using the method 200 by employing the input current sensor 306 and the phase current sensors 308. The input current sensor 306 and the phase current sensors 308 may be less expensive compared to high-bandwidth current sensors that may be required for capacitor current sensing applications.

At act 208, the method 200 includes applying Goertzel algorithm to determine a first z-domain equation H(z)I_{cap} of the capacitor current I_{cap} and a second z-domain equation H(z)V_{dc} of the DC link capacitor voltage V_{dc}.

In some embodiments, the first z-domain equation H(z)I_{cap} of the capacitor current I_{cap} is:

$$H ( z ) Icap = \frac{1 - {w}^{k x} N x {Z}^{- 1}}{1 - 2 cos ( \frac{2 π kx}{N x} ) {Z}^{- 1} + {Z}^{- 2}} * Icap$$

wherein Nx is a number of samples and Kx is:

$$K x = \frac{N x}{1 / Nx * Ts}$$

wherein Ts is a sampling time.

In some embodiments, the number of samples Nx and the sampling time Ts may be based on a switching frequency of the power converter 300.

Further, in some embodiments, the second z-domain equation H(z)V_{dc} of the DC link capacitor voltage V_{dc} is:

$$H ( z ) Vdc = \frac{1 - {w}^{k x} N x {Z}^{- 1}}{1 - 2 cos ( \frac{2 π kx}{N x} ) {Z}^{- 1} + {Z}^{- 2}} * Vdc$$

At act 210, the method 200 includes determining an estimated equivalent series resistance (ESR) and an estimated capacitance of the capacitor 302 based on the first z-domain equation H(z)I_{cap} of the capacitor current I_{cap} and the second z-domain equation H(z)V_{dc} of the DC link capacitor voltage V_{dc}.

In some embodiments, the estimated ESR of the capacitor 302 is estimated from the equation:

$$estimated ESR = Real ( \frac{H ( z ) V d c}{H ( z ) I c a p} )$$

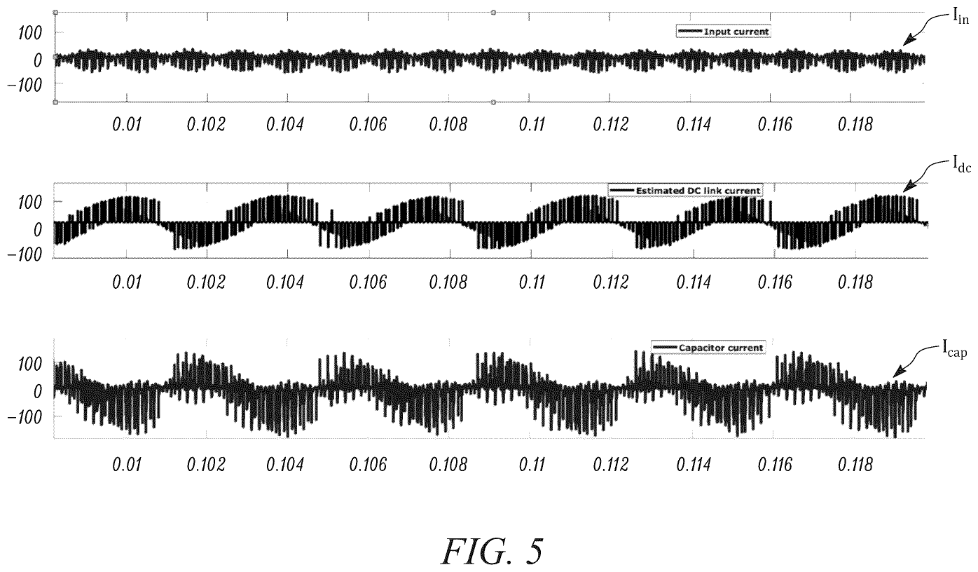

Furthermore, in some embodiments, the estimated capacitance of the capacitor 302 is estimated from the equation:

$$estimated capacitance = Imag ( \frac{H ( z ) Vdc}{H ( z ) Icap} ) * abs ( 1 / ( 2 * pi * fd ) )$$

wherein fd is a dominant frequency component (shown in FIG. 5).

In some embodiments, the method 200 further includes identifying the dominant frequency component fd based on the DC link capacitor voltage V_{dc}. In some embodiments, the dominant frequency component fd is about ±5% of the switching frequency of the power converter 300.

Therefore, the method 200 may rely on measuring the switching current harmonics to estimate the estimate capacitance and the estimate ESR.

At act 212, the method 200 includes retrieving an initial ESR and an initial capacitance of the capacitor 302. In some embodiments, the initial ESR and the initial capacitance of the capacitor 302 may be retrieved from the memory 104 communicably coupled to the processor 102. In some other embodiments, the initial ESR and the initial capacitance of the capacitor 302 may be retrieved from an external database (not shown) communicably coupled to the processor 102.

At act 214, the method 200 includes comparing the estimated ESR with the initial ESR and/or the estimated capacitance with the initial capacitance to determine when the capacitor 302 is degraded, short-circuited, or open-circuited. In some embodiments, the method 200 includes pausing an operation of the power converter 300 upon determining that the capacitor 302 is degraded, short-circuited, or open-circuited. In some embodiments, the method 200 includes stopping the operation of the power converter 300 upon determining that the capacitor 302 is degraded, short-circuited, or open-circuited.

In some embodiments, the method 200 further includes indicating that the capacitor 302 is degraded when the estimated ESR is greater than the initial ESR by at least 10% of the initial ESR.

In some embodiments, the method 200 further includes indicating that the capacitor 302 is degraded when the estimated capacitance is less than the initial capacitance by at least 5% of the initial capacitance and at most 50% of the initial capacitance. In other words, the method 200 includes indicating that the capacitor 302 is degraded when the estimated capacitance is less than the initial capacitance between 5% and 50% of the initial capacitance.

In some embodiments, the method 200 further includes indicating that the capacitor 302 is short-circuited when the estimated ESR is less than the initial ESR by at least 100% of the initial ESR.

In some embodiments, the method 200 includes indicating that the capacitor 302 is open-circuited when the estimated capacitance is less than the initial capacitance by at least 50% of the initial capacitance.

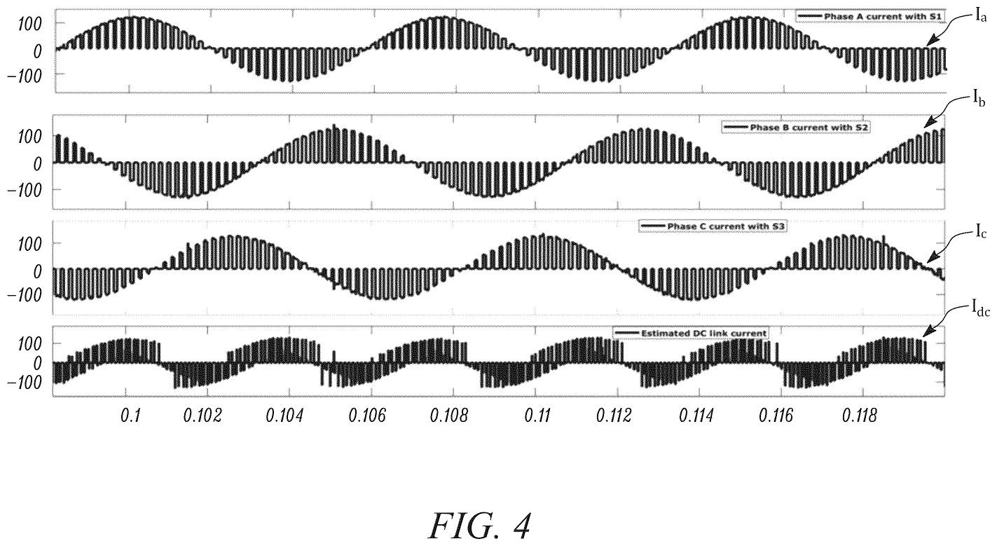

FIG. 4 shows an exemplary graphical representation of the current phases Iₐ, I_{b}, I_{c}. FIG. 4 further shows the DC link current I_{dc} calculated based on the switching pulses SP1, SP2, SP3 (shown in FIG. 1) and the phase currents Iₐ, I_{b}, I_{c}.

FIG. 5 shows an exemplary graphical representation of the input current Lin and the DC link current I_{dc} (also shown in FIG. 4). FIG. 5 further shows the capacitor current I_{cap} calculated based on the DC link current I_{dc} and the input current Iᵢₙ.

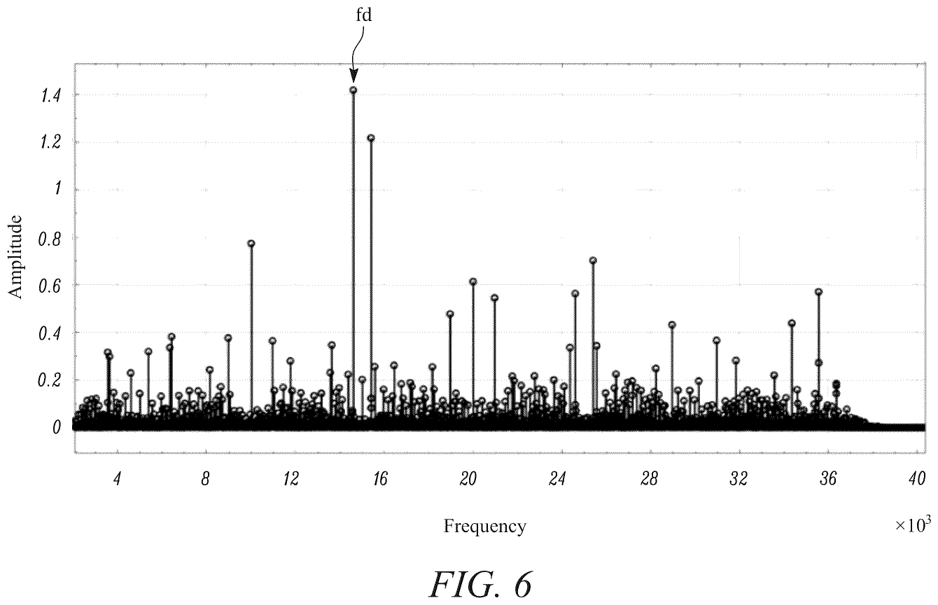

FIG. 6 shows an exemplary graph depicting an amplitude versus a frequency of the DC link capacitor voltage V_{dc} shown in FIG. 1. FIG. 6 further shows the dominant frequency component fd of the DC link capacitor voltage V_{dc}.

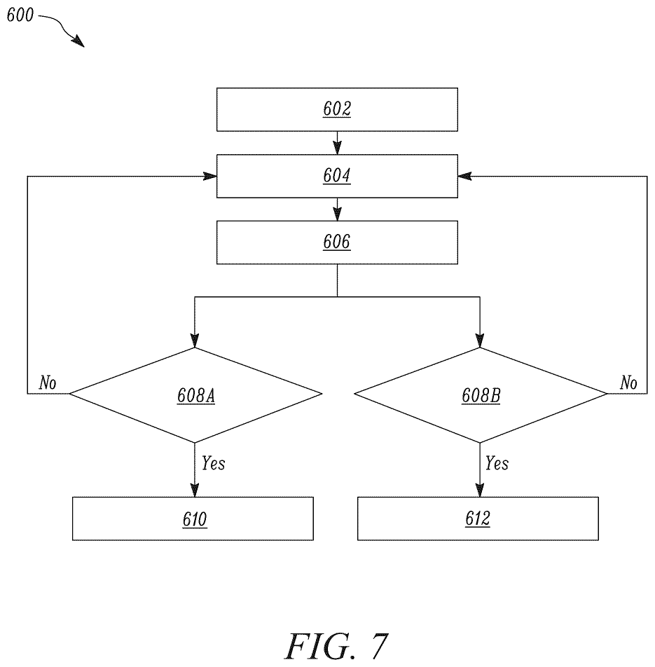

FIG. 7 shows a flow chart of a method 600 for determining the estimated ESR of the capacitor 302 shown in FIG. 1, according to an embodiment of the present disclosure. FIG. 7 is described with further reference to FIGS. 1-6.

The method 600 includes act 602, which is equivalent to act 202 of the method 200. Specifically, at act 602, the method 600 includes acquiring the DC link capacitor voltage V_{dc}, the input current Iᵢₙ, the phase currents Iₐ, I_{b}, I_{c}, and the switching pulses SP1, SP2, SP3 of the power converter 300.

The method 600 further includes act 604, which is equivalent to act 208 of the method 200. Specifically, at act 604, the method 600 includes applying the Goertzel algorithm to determine the first z-domain equation H(z)I_{cap} of the capacitor current I_{cap} and the second z-domain equation H(z)V_{dc} of the DC link capacitor voltage V_{dc}.

The method 600 further includes act 606, which includes determining the estimated ESR based on the first z-domain equation H(z)I_{cap} of the capacitor current I_{cap} and the second z-domain equation H(z)V_{dc} of the DC link capacitor voltage V_{dc}.

The method 600 further includes act 608A, which includes determining when the estimated ESR is greater than the initial ESR by at least 10% of the initial ESR. The method 600 proceeds to act 610 including indicating that the capacitor 302 is degraded when the estimated ESR is greater than the initial ESR by at least 10% of the initial ESR, otherwise the method 600 proceeds to act 604.

The method 600 further includes act 608B, which includes determining when the estimated ESR is less than the initial ESR by at least 100% of the initial ESR. The method 600 proceeds to act 612 including indicating that the capacitor 302 is short-circuited when the estimated ESR is less than the initial ESR by at least 100% of the initial ESR, otherwise the method 600 proceeds to act 604.

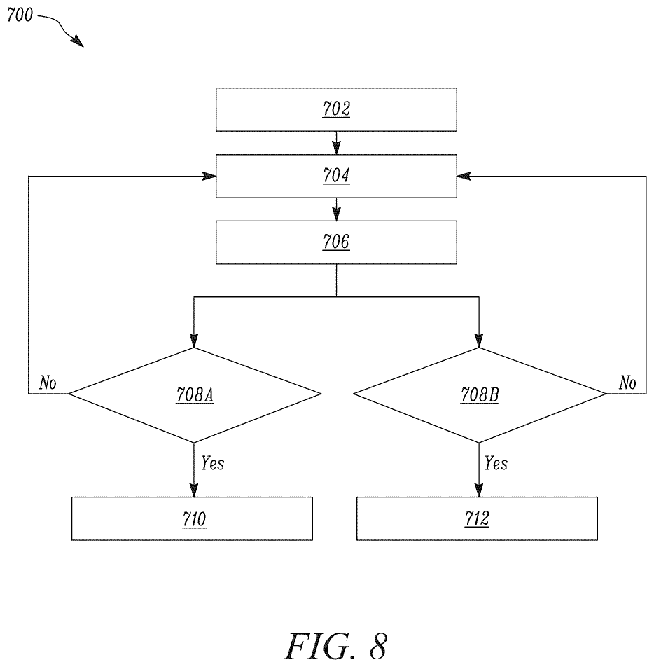

FIG. 8 shows a flow chart of a method 700 for determining the estimated capacitance of the capacitor 302 shown in FIG. 1, according to an embodiment of the present disclosure. FIG. 8 is described with further reference to FIGS. 1-6.

The method 700 includes act 702, which is equivalent to act 202 of the method 200. Specifically, at act 702, the method 700 includes acquiring the DC link capacitor voltage Vac, the input current Iᵢₙ, the phase currents Iₐ, I_{b}, I_{c}, and the switching pulses SP1, SP2, SP3 of the power converter 300.

The method 700 further includes act 704, which is equivalent to act 208 of the method 200. Specifically, at act 704, the method 700 includes applying the Goertzel algorithm to determine the first z-domain equation H(z)I_{cap} of the capacitor current I_{cap} and the second z-domain equation H(z)V_{dc} of the DC link capacitor voltage V_{dc}.

The method 700 further includes act 706, which includes determining the estimated ESR based on the first z-domain equation H(z)I_{cap} of the capacitor current I_{cap} and the second z-domain equation H(z)V_{dc} of the DC link capacitor voltage V_{dc}.

The method 700 further includes act 708A, which includes determining when the estimated capacitance is less than the initial capacitance by at least 5% of the initial capacitance and at most 50% of the initial capacitance. The method 700 proceeds to act 710 including indicating that the capacitor 302 is degraded when the estimated capacitance is less than the initial capacitance by at least 5% of the initial capacitance and at most 50% of the initial capacitance, otherwise the method 700 proceeds to act 704.

The method 700 further includes act 708B, which includes determining when the estimated capacitance is less than the initial capacitance by at least 50% of the initial capacitance. The method 700 proceeds to act 712 including indicating that the capacitor 302 is open-circuited when the estimated capacitance is less than the initial capacitance by at least 50% of the initial capacitance, otherwise the method 700 proceeds to act 704.

Referring to FIGS. 1 to 8, the method 200 may enable equipment health monitoring (EHM) and remaining useful life estimation of the capacitor 302 in the power converter 300. The method 200 may be applied to existing power converters by accessing terminals that may be available for a user by acquiring the DC link capacitor voltage V_{dc}, the input current Iᵢₙ, the phase currents Iₐ, I_{b}, I_{c}, and the switching pulses SP1, SP2, SP3 of the power converter 300. These parameters may be easy to obtain using available data and using inexpensive sensors and may not require any customized circuits to extract any signature. Therefore, the method 200 may be easily applied to any commercial off-the-shelf as well as in-house power converter systems. The method 200 may further provide an early detection of degradation, short-circuits, or open-circuits, which further may enable to prevent the power converter failures. The method 200 may therefore reduce maintenance costs. Further, the method 200 uses the estimated capacitance and the estimated ESR and therefore may be applied to dominant capacitor technologies.

List of reference signs

| | |
|---|---|
| 100 | System |
| 102 | Processor |
| 104 | Memory |
| 200 | Method |
| 202-214 | Acts |
| 300 | Power Converter |
| 302 | Capacitor |
| 304 | Voltage Sensor |
| 306 | Input Current Sensor |
| 308 | Phase Current Sensors |
| 320 | DC source |
| 330 | Load |
| 340 | Controller |
| 600 | Method |
| 602-612 | Acts |
| 700 | Method |
| 702-712 | Acts |
| fd | Dominant Frequency Component |
| V_{dc} | DC Link Capacitor Voltage |
| I_{dc} | DC Link Current |
| I_{cap} | Capacitor Current |
| Iᵢₙ | Input Current |
| Iₐ-I_{c} | Phase Currents |
| S1-S6 | Switches |
| SP1-SP3 | Switching Pulses |

1. A method for monitoring a health of a capacitor of a power converter, the method comprising:
acquiring a direct current (DC) link capacitor voltage, an input current, phase currents, and switching pulses of the power converter;
calculating a DC link current based on the switching pulses and the phase currents;
calculating a capacitor current based on the DC link current and the input current;
applying a Goertzel algorithm to determine a first z-domain equation of the capacitor current and a second z-domain equation of the DC link capacitor voltage;
determining an estimated Equivalent Series Resistance (ESR) and an estimated capacitance of the capacitor based on the first z-domain equation of the capacitor current and the second z-domain equation of the DC link capacitor voltage;
retrieving an initial ESR and an initial capacitance of the capacitor; and
comparing the estimated ESR with the initial ESR and/or the estimated capacitance with the initial capacitance to determine when the capacitor is degraded, short-circuited, or open-circuited.

2. The method of claim 1, further comprising:
pausing an operation of the power converter upon determining that the capacitor is degraded, short-circuited, or open-circuited.

3. The method of claim 1, wherein the DC link capacitor voltage is acquired from a voltage sensor.

4. The method of claim 1, wherein the input current is acquired from an input current sensor.

5. The method of claim 1, wherein the phase currents are acquired from corresponding phase current sensors.

6. The method of claim 1, wherein the switching pulses are acquired from a controller of the power converter.

7. The method of claim 1, wherein the DC link current is calculated from the following equation:
$${I}_{d c} = S P 1 * {I}_{a} + S P 2 * {I}_{b} + S P 3 * {I}_{c} ,$$
wherein:
I_{dc} is the DC link current;
SP1, SP2, and SP3 are the switching pulses; and
Iₐ, I_{b}, and I_{c} are the phase currents.

8. The method of claim 1, wherein the capacitor current is calculated by subtracting the DC link current from the input current.

9. The method of claim 1, wherein the first z-domain equation of the capacitor current is:
$$H ( z ) Icap = \frac{1 - {w}^{k x} N x {Z}^{- 1}}{1 - 2 cos ( \frac{2 π kx}{N x} ) {Z}^{- 1} + {Z}^{- 2}} * Icap$$
wherein:
H(z)I_{cap} is the first z-domain equation;
I_{cap} is the capacitor current;
Nx is a number of samples;
$$Kx = \frac{N x}{\frac{1}{Nx * T s}} ;$$
and
Ts is a sampling time.

10. The method of claim 9, wherein the second z-domain equation of the DC link capacitor voltage (Vac) is:
$$H ( z ) Vdc = \frac{1 - {w}^{k x} N x {Z}^{- 1}}{1 - 2 cos ( \frac{2 π kx}{N x} ) {Z}^{- 1} + {Z}^{- 2}} * Vdc$$
wherein H(z)V_{dc} is the second z-domain equation.

11. The method of claim 1, wherein the second z-domain equation of the DC link capacitor voltage (V_{dc}) is:
$$H ( z ) Vdc = \frac{1 - {w}^{k x} N x {Z}^{- 1}}{1 - 2 cos ( \frac{2 π kx}{N x} ) {Z}^{- 1} + {Z}^{- 2}} * Vdc$$
wherein:
H(z)V_{dc} is the second z-domain equation;
I_{cap} is the capacitor current;
Nx is a number of samples;
$$Kx = \frac{N x}{\frac{1}{Nx * T s}} ;$$
and
Ts is a sampling time.

12. The method of claim 1, wherein the estimated ESR of the capacitor is estimated from the following equation:
$$estimated ESR = Real ( \frac{H ( z ) V d c}{H ( z ) I c a p} ) ,$$
wherein:
H(z)I_{cap} is the first z-domain equation; and
H(z)V_{dc} is the second z-domain equation.

13. The method of claim 1, further comprising:
identifying a dominant frequency component based on the DC link capacitor voltage.

14. The method of claim 13, wherein the estimated capacitance of the capacitor is estimated from the following equation:
$$estimated capacitance = Imag ( \frac{H ( z ) V d c}{H ( z ) I c a p} ) * abs ( \frac{1}{2 * p i * f d} ) ,$$
wherein:
H(z)I_{cap} is the first z-domain equation;
H(z)V_{dc} is the second z-domain equation; and
fd is the dominant frequency component.

15. The method of claim 1, further comprising:
indicating that the capacitor is degraded when the estimated ESR is greater than the initial ESR by at least 10% of the initial ESR.

16. The method of claim 1, further comprising:
indicating that the capacitor is short-circuited when the estimated ESR is less than the initial ESR by at least 100% of the initial ESR.

17. The method of claim 1, further comprising:
indicating that the capacitor is degraded when the estimated capacitance is less than the initial capacitance by at least 5% of the initial capacitance and at most 50% of the initial capacitance.

18. The method of claim 1, further comprising:
indicating that the capacitor is open-circuited when the estimated capacitance is less than the initial capacitance by at least 50% of the initial capacitance.

19. A system comprising:
a processor; and
a memory having stored therein a plurality of instructions that when executed by the processor causes the system to:
acquire a direct current (DC) link capacitor voltage, an input current, phase currents, and switching pulses of a power converter;
calculate a DC link current based on the switching pulses and the phase currents;
calculate a capacitor current based on the DC link current and the input current;
apply a Goertzel algorithm to determine a first z-domain equation of the capacitor current and a second z-domain equation of the DC link capacitor voltage;
determine an estimated Equivalent Series Resistance (ESR) and an estimated capacitance of the capacitor based on the first z-domain equation of the capacitor current and the second z-domain equation of the DC link capacitor voltage;
retrieve an initial ESR and an initial capacitance of the capacitor; and
compare the estimated ESR with the initial ESR and/or the estimated capacitance with the initial capacitance to determine when the capacitor is degraded, short-circuited, or open-circuited.
